(19) United States
(12) Patent Application Publication
(10) Pub. No.: US 2015/0225872 A1
(43) Pub. Date: Aug. 13, 2015

(54) SINGLE CRYSTAL PRODUCTION APPARATUS, CRUCIBLE FOR USE THEREIN, AND METHOD OF PRODUCING SINGLE CRYSTAL

(71) Applicants: NIPPON STEEL & SUMITOMO METAL CORPORATION, Tokyo (JP); TOYOTA JIDOSHA KABUSHIKI KAISHA, Aichi (JP)

(72) Inventors: Kazuhito Kamei, Kitakyushu-shi (JP); Kazuhiko Kusunoki, Nishinomiya-shi (JP); Nobuyoshi Yashiro, Itami-shi (JP); Nobuhiro Okada, Kisarazu-shi (JP); Koji Moriguchi, Nishinomiya-shi (JP); Hironori Daikoku, Susono-shi (JP); Motohisa Kado, Gotenba-shi (JP); Hidemitsu Sakamoto, Susono-shi (JP)

(73) Assignee: TOYOTA JIDOSHA KABUSHIKI KAISHA, Aichi (JP)

(21) Appl. No.: 14/424,578

(22) PCT Filed: Aug. 30, 2013
(86) PCT No.: PCT/JP2013/005131

§ 371 Date: Feb. 27, 2015

(30) Foreign Application Priority Data
Sep. 4, 2012 (JP) 2012-194250

(51) Int. Cl. C30B 19/10; C30B 29/36; C30B 19/12; C30B 19/04; C30B 19/06

(52) U.S. Cl. CPC C30B 19/10; C30B 19/04; C30B 19/062; C30B 19/067; C30B 19/068; C30B 19/12; C30B 29/36

(57) ABSTRACT

The production apparatus is used in production of single crystals by solution growth techniques. The production apparatus includes a seed shaft, a crucible, and a drive source. The seed shaft has a lower end surface to which a seed crystal is to be attached. The crucible contains a solution from which a single crystal is made. The drive source causes the crucible to rotate, and also varies the rotational speed of the crucible. The inner peripheral surface of the crucible includes a flow control surface which defines a non-circular cross-sectional shape. This single crystal production apparatus is capable of strongly stirring the solution contained in the crucible.

### TECHNICAL FIELD

The present invention relates to a single crystal production apparatus, a crucible for use therein, and a method of producing single crystals. In particular, it relates to a production apparatus for producing single crystals by solution growth techniques, a crucible for use therein, and a method of producing single crystals by solution growth techniques.

### BACKGROUND ART

As a method of producing single crystals, solution growth techniques are known. In solution growth techniques, a single crystal is grown by bringing a seed crystal into contact with a solution from which the single crystal is made.

In certain types of single crystals such as, for example, a SiC single crystal, crystal growth progresses by lateral growth of steps. In such single crystals that undergo step-flow growth, step bunching occurs when the growth of an upstream step overtakes the growth of a downstream step. If step bunching progresses, inclusions occur as a result of trapping of solution, for example. This leads to reduced quality of the resulting single crystal.

Japanese Patent Application Publication No. 2006-117441 discloses a method of producing SiC single crystals of good quality by inhibiting the occurrence of inclusions. In this publication, a melt in a crucible is stirred by periodically varying the rotational speed of the crucible, or the rotational speed and the rotational direction of the crucible. With this, the occurrence of inclusions is inhibited.

### CITATION LIST

### Patent Literature

Patent Literature 1: Japanese Patent Application Publication No. 2006-117441

### SUMMARY OF INVENTION

### Technical Problem

However, there is a need for techniques that are capable of inhibiting the occurrence of step bunching more stably so that the occurrence of inclusions can be inhibited.

An object of the present invention is to provide a single crystal production apparatus, a crucible for use therein, and a method of producing single crystals which are capable of inhibiting step bunching more stably.

### Solution to Problem

A single crystal production apparatus according to embodiments of the present invention is used in production of single crystals by solution growth techniques. The production apparatus includes a seed shaft, a crucible, and a drive source. The seed shaft has a lower end surface to which a seed crystal is to be attached. The crucible contains a solution from which a single crystal is made. The drive source causes the crucible to rotate, and also varies the rotational speed of the crucible. The inner peripheral surface of the crucible includes a flow control surface which defines a non-circular cross-sectional shape.

A crucible according to embodiments of the present invention is used in a production apparatus for producing single crystals by solution growth techniques (e.g., the production apparatus mentioned above), and is configured to contain a material for single crystals. The crucible has an inner peripheral surface, and the inner peripheral surface includes a flow control surface which defines a non-circular cross-sectional shape.

A method of producing single crystals according to embodiments of the present invention uses the production apparatus as described above. The production method is a method of producing single crystals by solution growth techniques. It includes the steps of: preparing a seed shaft having a lower end surface to which a seed crystal is to be attached; preparing a crucible configured to contain a solution from which the single crystal is made, the crucible having an inner peripheral surface, the inner peripheral surface including a flow control surface, the flow control surface defining a non-circular cross-sectional shape; forming the solution; and bringing the seed crystal into contact with the solution and growing the single crystal, wherein the step of growing the single crystal includes causing the crucible to rotate and varying a rotational speed of the crucible.

### Advantageous Effects of Invention

A single crystal production apparatus, a crucible for use therein, and a method of producing single crystals, according to embodiments of the present invention, are capable of inhibiting step bunching during growth of single crystals more stably.

### BRIEF DESCRIPTION OF DRAWINGS

FIG. 1 is a schematic diagram of a single crystal production apparatus according to embodiments of the present invention.

FIG. 2 is a sectional view of a crucible included in the production apparatus shown in FIG. 1.

FIG. 3 is a plan view of a flow control portion included in the crucible shown in FIG. 2.

FIG. 4 is a plan view of a variation of the flow control portion.

FIG. 5 is a schematic diagram of a production apparatus used for producing a SiC single crystal of Comparative Example.

FIG. 6 is a photograph of a section of a SiC single crystal produced using the production apparatus shown in FIG. 1 (Example 1).

FIG. 7 is a photograph of a section of a SiC single crystal produced using the production apparatus shown in FIG. 1 (Example 2).

FIG. 8 is a photograph of a section of a SiC single crystal produced using the production apparatus shown in FIG. 5.

### DESCRIPTION OF EMBODIMENTS

A single crystal production apparatus according to embodiments of the present invention is used in production of single crystals by solution growth techniques. The production apparatus includes a seed shaft, a crucible, and a drive source. The seed shaft has a lower end surface to which a seed crystal is to be attached. The crucible contains a solution from which a single crystal is made. The drive source causes the crucible to rotate, and also varies the rotational speed of the crucible. The inner peripheral surface of the crucible includes a flow control surface which defines a non-circular cross-sectional shape.

When the rotational speed of the crucible changes, the law of inertia works to maintain the flow of the solution in the crucible before the change of the rotational speed. It is to be noted that the cross-sectional shape defined by the flow control surface, i.e., the shape of the cross-section, perpendicular to the axis, of the opening that is formed by the flow control surface is non-circular. Because of this, when the rotational speed of the crucible is varied, the flow of the solution that exists within the flow control surface becomes turbulent. As a result, a vortex flow is formed within the flow control surface. This flow exerts influence on the flow of the solution that exists in regions other than within the flow control surface. Thus, a similar flow is formed in the solution that exists in regions other than within the flow control surface. As a result, clusters of the solute that exist in the solution are dissociated, which results in inhibiting step bunching and improving the quality of single crystals.

In particular, when the rotational speed of the crucible is decreased, the flow of the solution that exists within the flow control surface becomes more turbulent than when the rotational speed of the crucible is increased. Thus, a larger vortex flow is formed within the flow control surface. As a result, step bunching is further inhibited and the quality of single crystals is further improved.

Preferably, the cross-sectional shape defined by the flow control surface has point symmetry. This allows formation of a vortex flow within the flow control surface when the rotational speed of the crucible is varied.

Preferably, the cross-sectional shape defined by the flow control surface is oval. This allows formation of an even stronger vortex flow within the flow control surface when the rotational speed of the crucible is varied.

Preferably, the crucible includes a cylindrical portion, a bottom portion, and a flow control portion. The bottom portion is located at the lower end of the cylindrical portion. The flow control portion is disposed in contact with the cylindrical portion, and has an opening extending vertically. In the flow control portion, the inner surface of the opening constitutes the flow control surface.

In this case, by modifying the flow control portion, the capacity or the like within the flow control surface, for example, can be appropriately modified depending on the volume or the like of the solution that is contained in the crucible.

Preferably, the flow control portion is positioned in contact with the bottom portion. In such a case, the distance between the flow control portion and the seed crystal can be larger. As a result, it is less likely that the growth of single crystals is hindered by the provision of the flow control portion.

Preferably, the outer peripheral surface of the flow control portion includes a first outer peripheral surface and a second outer peripheral surface. The first outer peripheral surface is in contact with the cylindrical portion. The second outer peripheral surface forms a space between itself and the cylindrical portion.

In such a case, the volume of the flow control portion can be reduced. Thus, the heat capacity of the flow control portion can be reduced. As a result, in the solution contained in the crucible, a portion thereof that exists near the flow control portion is less likely to experience a temperature decrease.

Single crystals that may be produced using the above production apparatus are not particularly limited as long as they are single crystals that undergo step-flow growth. The single crystal may be, for example, a SiC single crystal. When producing a SiC single crystal, a SiC seed crystal is used as the seed crystal, and a Si—C solution is used as the solution. A Si—C solution is a solution of a Si or Si alloy melt in which carbon (C) is dissolved.

A crucible according to embodiments of the present invention is used in the above production apparatus.

A method of producing single crystals according to embodiments of the present invention uses the production apparatus as described above.

Hereinafter, embodiments of the present invention will be described with reference to the drawings. The same reference symbols will be used throughout the drawings to refer to the same or like parts, and a description thereof will not be repeated.

### [Production Apparatus]

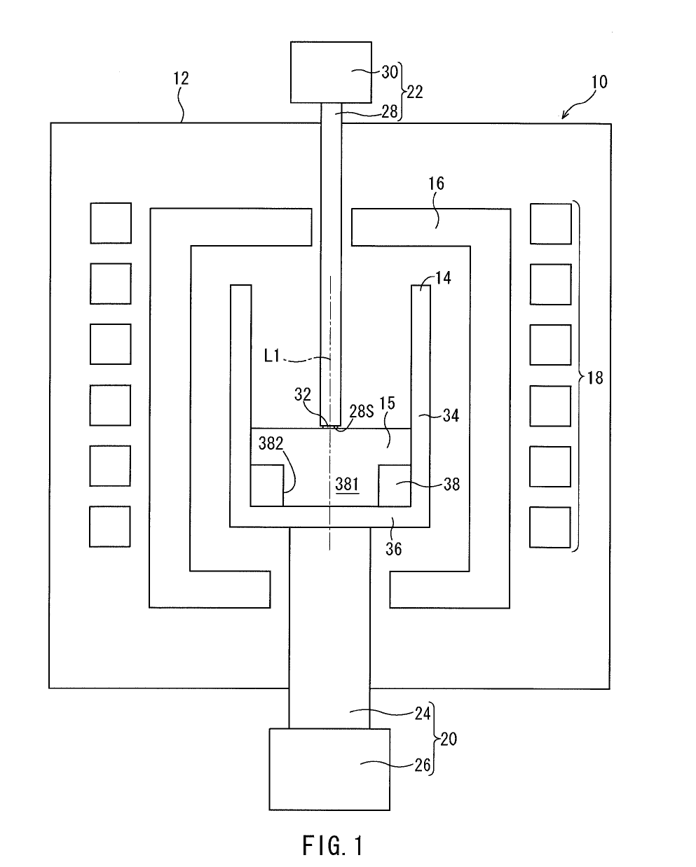

FIG. 1 is a schematic diagram showing a configuration of a single crystal production apparatus 10 according to embodiments of the present invention. Although, in the present embodiment, the description refers to the production apparatus that is used for production of SiC single crystals, the production apparatus of the present invention may be used in production of single crystals other than SiC single crystals (for example, a single crystal of AlN).

The production apparatus 10 includes a chamber 12, a crucible 14, an insulating member 16, a heating device 18, a rotation device 20, and a lifting and lowering device 22.

The chamber 12 accommodates the crucible 14. During the production of a SiC single crystal, the chamber 12 is cooled.

The crucible 14 contains a Si—C solution 15. The Si—C solution 15 is a material from which a SiC single crystal is made. The Si—C solution 15 includes silicon (Si) and carbon (C).

The raw material for the Si—C solution 15 is, for example, Si alone or a mixture of Si and another metal element. The raw material is heated to form a melt, and carbon (C) is dissolved in the melt, whereby the Si—C solution 15 is formed. Examples of another metal element include titanium (Ti), manganese (Mn), chromium (Cr), cobalt (Co), vanadium (V) and iron (Fe). Of these metal elements, preferred metal elements are Ti, Cr, and Fe. More preferred metal elements are Ti and Cr.

Preferably, the crucible 14 includes carbon. When this is the case, the crucible 14 serves as a source of carbon that is supplied to the Si—C solution 15. The crucible 14 may be a crucible made of graphite or a crucible made of SiC, for example. The crucible 14 may have a SiC coating on its internal surface.

The insulating member 16 is made of insulating material and surrounds the crucible 14.

The heating device 18 may be, for example, a high frequency coil, and surrounds side walls of the insulating member 16. The heating device 18 heats the crucible 14 that contains the raw material for the Si—C solution 15 by induction heating, so that the Si—C solution 15 is formed. Further, the heating device 18 maintains the Si—C solution 15 at the crystal growth temperature. The crystal growth temperature depends on the composition of the Si—C solution 15. The crystal growth temperature is, for example, 1600 to 2000° C.

The rotation device 20 includes a rotatable shaft 24 and a drive source 26.

The rotatable shaft 24 extends in the height direction of the chamber 12 (the vertical direction in FIG. 1). The upper end of the rotatable shaft 24 is located inside the insulating member 16. The crucible 14 is disposed at the upper end of the rotatable shaft 24. The lower end of the rotatable shaft 24 is located outside the chamber 12.

The drive source 26 is placed below the chamber 12. The drive source 26 is connected to the rotatable shaft 24. The drive source 26 causes the rotatable shaft 24 to rotate about the central axis of the rotatable shaft 24. With this, the crucible 14 (Si—C solution 15) rotates about the central axis L1. The drive source 26 varies the rotational speed of the rotatable shaft 24, or the rotational speed and rotational direction of the rotatable shaft 24.

The lifting and lowering device 22 includes a seed shaft 28 and a drive source 30.

The seed shaft 28 extends in the height direction of the chamber 12. The seed shaft 28 is made of graphite, for example. The upper end of the seed shaft 28 is located outside the chamber 12. A SiC seed crystal 32 is to be attached to the lower end surface 28S of the seed shaft 28.

The SiC seed crystal 32 is in the shape of a plate, and the top surface thereof is to be attached to the lower end surface 28S. In the present embodiment, the entire top surface of the SiC seed crystal 32 is in contact with the lower end surface 28S. The lower surface of the SiC seed crystal 32 serves as the crystal growth surface.

The SiC seed crystal 32 is made of a SiC single crystal. Preferably, the SiC seed crystal 32 has the same crystal structure as that of the SiC single crystal that is to be produced. For example, when a SiC single crystal of the 4H polytype is to be produced, a SiC seed crystal 32 of the 4H polytype is used. When a SiC seed crystal 32 of the 4H polytype is used, it is preferred that the crystal growth surface be the (0001) plane or the (000-1) plane, or a plane that is 8° or less off-axis from the (0001) plane or the (000-1) plane. In such a case, SiC single crystals are grown stably.

The drive source 30 is placed above the chamber 12. The drive source 30 is connected to the seed shaft 28.

The drive source 30 lifts and lowers the seed shaft 28. With this, the crystal growth surface of the SiC seed crystal 32 attached to the lower end surface 28S of the seed shaft 28 can be brought into contact with the surface of the Si—C solution 15 contained in the crucible 14.

The drive source 30 causes the seed shaft 28 to rotate about the central axis of the seed shaft 28. With this, the SiC seed crystal 32 attached to the lower end surface 28S of the seed shaft 28 rotates.

### [Crucible]

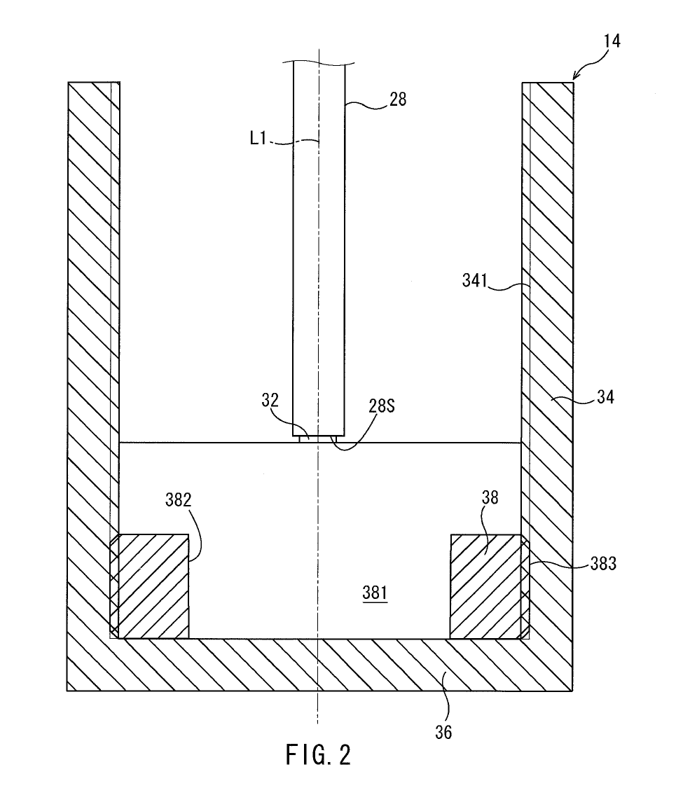

With reference to FIG. 2, a description of the crucible 14 is given. The crucible 14 includes a cylindrical portion 34, a bottom portion 36, and a flow control portion 38.

The cylindrical portion 34 extends in the vertical direction. The cylindrical portion 34 may be, for example, a cylinder. The inside diameter of the cylindrical portion 34 is sufficiently greater than the outside diameter of the seed shaft 28.

The bottom portion 36 is located at the lower end of the cylindrical portion 34. The bottom portion 36 is integrally formed with the cylindrical portion 34, for example.

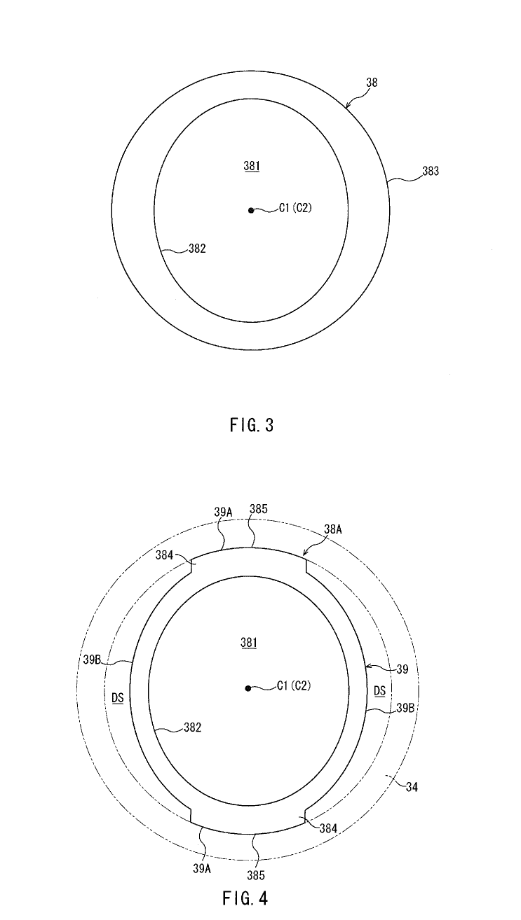

The flow control portion 38 is a ring-shaped member and has an opening 381 that extends vertically. In the flow control portion 38, the inner surface of the opening 381 constitutes the flow control surface 382. As shown in FIG. 3, the cross-sectional shape defined by the flow control surface 382, i.e., the shape of the cross-section, perpendicular to the axis, of the opening 381 is non-circular.

The cross-sectional shape defined by the flow control surface is not particularly limited as long as it is non-circular, and may be, for example, polygonal. In this case, the polygon is preferably a rectangle or a pentagon, and, in particular, preferably one without acute angles.

In addition, it is further preferred that the cross-sectional shape defined by the flow control surface has no singular point. In such a case, a stronger vortex flow can be formed. Such cross-sectional shape to be defined by the flow control surface may be, for example, obtained by rounding corners of a polygon. In this case, the polygon is preferably a triangle, a rectangle, or a pentagon. When the cross-sectional shape defined by the flow control surface has no singular point, the minimum radius of curvature of the shape is preferably 5 mm or more.

In the present embodiment, the cross-sectional shape defined by the flow control surface 382 is oval. That is, in the present embodiment, the cross-sectional shape defined by the flow control surface 382 has point symmetry. The “oval shape” as used herein includes not only an elliptical shape as geometrically defined but also an oval shape having one or more straight line portions (provided that the straight line portions do not form an acute angle, at the ends thereof, with a tangent line to the oval) and a generally oval shape formed by a plurality of straight lines. Examples of a generally oval shape formed by a plurality of straight lines include a hexagon in which the distance between one pair of opposite sides is longer than the distances between the other pairs of opposite sides, and a hexagon in which the distance between one pair of opposite angles is longer than the distances between the other pairs of opposite angles.

The opening 381 is located at a central region of the flow control portion 38. In the present embodiment, the center C1 of the opening 381 and the center C2 of the flow control portion 38 coincide with each other when viewed vertically. However, it is not necessary that the center C1 of the opening 381 and the center C2 of the flow control portion 38 exactly coincide with each other.

The flow control portion 38 is secured to the cylindrical portion 34. That is, the flow control surface 382 constitutes a part of the inner peripheral surface of the crucible 14. In the present embodiment, the cylindrical portion 34 has female threads 341 formed on its inner peripheral surface. The flow control portion 38 has male threads 383 formed on its outer peripheral surface. The flow control portion 38 is mounted to the cylindrical portion 34 by engaging the male threads 383 into the female threads 341. In the present embodiment, the flow control portion 38 is positioned in contact with the bottom portion 36. It is to be noted that the flow control portion 38 may instead be secured to the cylindrical portion 34 by an adhesive such as a carbon-based adhesive or the like.

### [Method of Producing SiC Single Crystals]

Methods of producing SiC single crystals using the production apparatus 10 are described. Firstly, the production apparatus 10 is prepared (preparation step). Next, the SiC seed crystal 32 is attached to the seed shaft 28 (attaching step). Next, the crucible 14 is placed within the chamber 12 and the Si—C solution 15 is formed (forming step). Next, the SiC seed crystal 32 is brought into contact with the Si—C solution 15 in the crucible 14 (contacting step). Next, a SiC single crystal is grown (growing step). Details of each step are described below.

### [Preparation Step]

Firstly, the production apparatus 10 is prepared.

### [Attaching Step]

Then, the SiC seed crystal 32 is attached to the lower end surface 28S of the seed shaft 28. In the present embodiment, the entire top surface of the SiC seed crystal 32 is in contact with the lower end surface 28S of the seed shaft 28.

### [Forming Step]

Next, the crucible 14 is placed on the rotatable shaft 24 within the chamber 12. The crucible 14 contains raw materials for the Si—C solution 15.

Next, the Si—C solution 15 is formed. Firstly, the chamber 12 is filled with an inert gas. Then, the raw material for the Si—C solution 15 in the crucible 14 is heated to its melting point or higher using the heating device 20. When the crucible 14 is one made of graphite, carbon from the crucible 14 is dissolved into the melt by heating the crucible 14, so that the Si—C solution 15 is formed. As the carbon in the crucible 14 is dissolved in the Si—C solution 15, the carbon concentration in the Si—C solution 15 approaches a saturation concentration.

### [Contacting Step]

Next, the seed shaft 28 is lowered by the drive source 30 to bring the crystal growth surface of the SiC seed crystal 32 into contact with the Si—C solution 15.

### [Growing Step]

After the crystal growth surface of the SiC seed crystal 32 is brought into contact with the Si—C solution 15, the Si—C solution 15 is held at the crystal growth temperature using the heating device 18. Further, in the Si—C solution 15, a region near the SiC seed crystal 32 is supercooled so that it is supersaturated with SiC.

The method of supercooling the region near the SiC seed crystal 32 in the Si—C solution 15 is not particularly limited. For example, one possible method is to control the heating device 20 so that the temperature of the region near the SiC seed crystal 32 in the Si—C solution 15 can be reduced to a level lower than the temperatures of the other regions. Alternatively, a coolant may be used to cool the vicinity of the SiC seed crystal 32 in the Si—C solution 15. Specifically, a coolant is circulated within the seed shaft 28. The coolant may be, for example, an inert gas such as helium (He) or argon (Ar). When a coolant is circulated within the seed shaft 28, the SiC seed crystal 32 is cooled. When the SiC seed crystal 32 is cooled, the region near the SiC seed crystal 32 in the Si—C solution 15 is also cooled.

While the region near the SiC seed crystal 32 in the Si—C solution 15 is held in the SiC supersaturated condition, the crucible 14 is caused to rotate. The drive source 26 varies the rotational speed of the crucible 14 during the crystal growth process. The rotational speed of the crucible 14 may be periodically varied or may not be periodically varied. The rotational direction of the crucible 14 may be varied in addition to the rotational speed of the crucible 14.

When the rotational speed of the crucible 14 is to be varied, the drive source 26 repeats one cycle of operations which include, for example: acceleration until a first preset rotational speed is reached; maintaining of the first preset rotational speed; and deceleration until a second preset rotational speed, which is lower than the first preset rotational speed, is reached.

When the rotational speed and the rotational direction of the crucible 14 are to be varied, the drive source 26 repeats one cycle of operations which include, for example: acceleration in a first rotational direction until a first preset rotational speed is reached; maintaining of the first preset rotational speed; deceleration from the first preset rotational speed until the rotation is stopped; acceleration in a second rotational direction opposite to the first rotational direction until a second preset rotational speed is reached; maintaining of the second preset rotational speed; and deceleration from the second preset rotational speed until the rotation is stopped.

In either case, it is not necessary that the first preset rotational speed and the second preset rotational speed are constant throughout the cycles, nor that the length of time between rotation at one preset rotational speed and rotation at the other preset rotational speed is constant throughout the cycles.

The seed shaft 28 may be rotated or may not be rotated. When the seed shaft 28 is to be rotated, the rotational direction of the seed shaft 28 may be the same as the rotational direction of the crucible 14 or be the opposite direction thereto. The rotational speed of the seed shaft 28 may be constant or be varied. The rotation of the seed shaft 28 may be synchronized with the rotation of the crucible 14. The seed shaft 28 may be lifted or may not be lifted.

According to the production method described above, when the rotational speed of the crucible 14 changes, the flow of the Si—C solution 15 in the opening 381 becomes turbulent, whereby a vortex flow is formed in the Si—C solution 15 within the opening 381. A flow of the Si—C solution 15 similar to the one within the opening 381 is also formed in the Si—C solution 15 that exists above the flow control portion 38. Thus, the Si—C solution 15 within the crucible 14 is stirred.

In particular, when the rotational speed of the crucible 14 is decreased, the flow of the solution 15 that exists within the opening 381 becomes more turbulent than when the rotational speed of the crucible 14 is increased, and therefore a larger or stronger vortex flow is formed. Also, when the rotational speed of the crucible 14 is decreased, the velocity of the flow of the Si—C solution 15, in a certain region thereof, increases compared to the velocity before the rotational speed is varied. Thus, the Si—C solution 15 within the crucible 14 is stirred more strongly.

When the Si—C solution 15 within the crucible 14 is stirred strongly, clusters of the solute that exists in the Si—C solution 15 are dissociated and therefore step bunching is inhibited. As a result, the quality of SiC single crystals is improved. To produce such advantageous effects, the cross-sectional shape defined by the flow control surface 382 has a major axis/minor axis ratio, preferably in the range of 1.1 to 2.0, and more preferably in the range of 1.1 to 1.3. If the major axis/minor axis ratio is too small (too close to one), the advantage of stirring the Si—C solution cannot be sufficiently achieved. On the other hand, if the major axis/minor axis ratio is too large, a large crucible tailored to the major axis will be necessary to form a large vortex flow. Because of this, stirring of the solution and high frequency heating thereof will become difficult, and moreover, the production costs will be increased.

In the present embodiment, the cross-sectional shape defined by the flow control surface 382 has point symmetry. This facilitates formation of a vortex flow within the opening 381 when the rotational speed of the crucible 14 is varied.

In the present embodiment, the cross-sectional shape defined by the flow control surface 382 is oval. This allows formation of an even larger or stronger vortex flow within the opening 381 when the rotational speed of the crucible 14 is varied.

In the present embodiment, the flow control portion 38 is secured to the cylindrical portion 34. Accordingly, the flow control portion 38 can be modified depending on the volume or the like of the Si—C solution 15 in the crucible 14.

In the present embodiment, the flow control portion 38 is positioned in contact with the bottom portion 36 of the crucible 14. Accordingly, a SiC single crystal that is to be grown is less likely to come into contact with the flow control portion 38.

In the crucible 14, the region where the flow control portion 38 has been mounted has increased heat capacity. Because of this, there is a concern that, even when the heating is performed at the same power, the temperature of the Si—C solution 15 might be decreased and SiC polycrystals might be precipitated. However, even if SiC polycrystals are precipitated, as long as the flow control portion 38 is positioned in contact with the bottom portion 36 of the crucible 14 as in the present embodiment, it is less likely that the SiC polycrystals adhere to the SiC single crystal.

### [Variation of Height Position of Flow Control Portion]

Although the flow control portion 38 is positioned in contact with the bottom portion 36 of the crucible 14 in the above embodiment, the height position of the flow control portion 38 is not particularly limited provided that the flow control portion 38 is immersed in the Si—C solution 15. For example, the flow control portion 38 may be mounted to the cylindrical portion 34 at a location spaced apart from the bottom portion 36. Preferably, the flow control portion 38 is disposed around the central region of heating when the heating device 18 heats the crucible 14. With this, precipitation of SiC polycrystals is inhibited.

### [Variation 1 of Flow Control Portion]

A variation of the flow control portion is shown in FIG. 4. The flow control portion 38A shown in FIG. 4 has a mounting portion 384 at opposite ends in the major axis direction of the opening 381 (the vertical direction in FIG. 4).

The mounting portion 384 has male threads 385 formed thereon. The flow control portion 38A is mounted to the cylindrical portion 34 by means of the male threads 385 and the female threads 341 of the crucible 14 which are formed on the cylindrical portion 34.

The outer peripheral surface 39 of the flow control portion 38A includes a first outer peripheral surface 39A and a second outer peripheral surface 39B.

The first outer peripheral surface 39A is a surface, in the mounting portion 384, where the male threads 385 are formed. The first outer peripheral surface 39A is brought into contact with the cylindrical portion 34 by engaging the mounting portion 384 with the cylindrical portion 34.

The second outer peripheral surface 39B is spaced apart from the cylindrical portion 34. Thus, a space DS is formed between the second outer peripheral surface 39B and the cylindrical portion 34.

The flow control portion 38A can be reduced in volume compared to the flow control portion 38 shown in FIGS. 1 to 3 because the second outer peripheral surface 39B is configured to be spaced apart from the cylindrical portion 34. Thus, the heat capacity of the flow control portion 38A can be reduced compared to that of the flow control portion 38. As a result, in the Si—C solution 15, a portion thereof that exists near the flow control portion 38A is less likely to experience a temperature decrease. Consequently, precipitation of SiC polycrystals can be inhibited.

### [Variation 2 of Flow Control Portion]

In the above embodiment, the flow control portion 38 that is formed separately from the cylindrical portion 34 has the flow control surface, but instead, for example, the cylindrical portion 34 may have a flow control surface. In such a case, the flow control portion may be integrally formed with the cylindrical portion 34.

### EXAMPLES

SiC single crystals were produced using the production apparatus shown in FIG. 1, and the quality of the produced SiC single crystals was inspected (Examples).

### Production Conditions for Example 1

In the crucible, the flow control portion was positioned in contact with the bottom portion. The length of the major axis of the opening was 110 mm. The length of the minor axis of the opening was 100 mm. The vertical length of the opening (the thickness of the flow control portion) was 20 mm. The length from the bottom portion of the crucible to the surface of the Si—C solution was 40 mm. The inside diameter of the crucible was 140 mm. The crystal growth temperature was 1950° C. The crystal structure of the SiC seed crystal was 4H.

During the crystal growth process, the rotational speed of the crucible was periodically varied. The preset rotational speed was 15 rpm. The length of time from the start of rotation to the time the preset rotational speed was reached was 5 seconds. The length of time in which the preset rotational speed was maintained was 5 seconds. The length of time from the rotation at the preset rotational speed to the time the rotation was stopped was 5 seconds. Such a rotation process was designated as one cycle, and this cycle was repeated. The period of time for crystal growth was 10 hours.

### Production Conditions for Example 2

In the crucible, the flow control portion was positioned in contact with the bottom portion. The length of the major axis of the opening was 130 mm. The length of the minor axis of the opening was 100 mm. The vertical length of the opening (the thickness of the flow control portion) was 20 mm. The length from the bottom portion of the crucible to the surface of the Si—C solution was 40 mm. The inside diameter of the crucible was 140 mm. The crystal growth temperature was 1950° C. The crystal structure of the SiC seed crystal was 4H.

During the crystal growth process, the rotational speed and rotational direction of the crucible were periodically varied between clockwise at 20 rpm and counterclockwise at 20 rpm. The length of time from the start of rotation to the time the rotational speed of 20 rpm was reached was 5 seconds. The length of time in which the rotational speed of 20 rpm was maintained was 10 seconds. The length of time from the state of rotating at 20 rpm in one rotational direction to the state of rotating at 20 rpm in the other rotational direction, with the state of zero rotational speed intervening therebetween, was 10 seconds. Such a rotation process was designated as one cycle, and this cycle was repeated. The period of time for crystal growth was 10 hours.

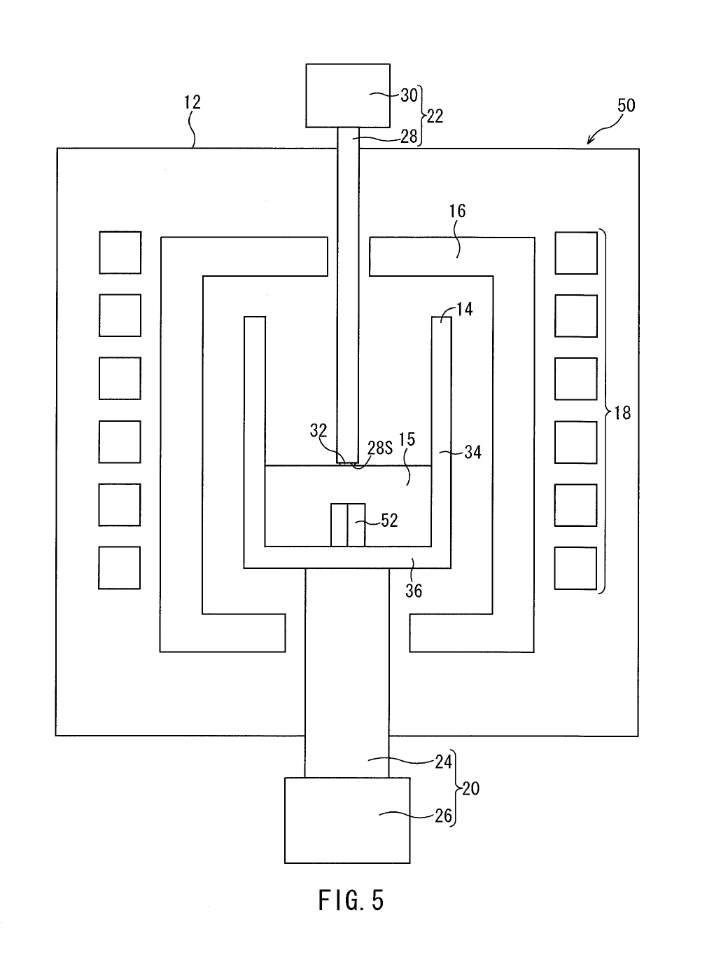

In addition, for comparison, a SiC single crystal was produced using a production apparatus 50 shown in FIG. 5, and the quality of the produced SiC single crystal was inspected (Comparative Example). The production apparatus 50 did not have a flow control portion 38. Instead, a stir bar 52 was provided at the center of the bottom portion 36. The stir bar 52 had a triangular cross-section.

### Production Conditions for Comparative Example

The height of the stir bar was 20 mm. The length from the bottom portion of the crucible to the surface of the Si—C solution was 50 mm. The inside diameter of the crucible was 140 mm. The crystal growth temperature was 1950° C. The crystal structure of the SiC seed crystal was 4H.

During the crystal growth process, the rotational speed of the crucible was periodically varied. The preset rotational speed was 20 rpm. The length of time from the start of rotation to the time the preset rotational speed was reached was 5 seconds. The length of time in which the preset rotational speed was maintained was 10 seconds. The length of time from the rotation at the preset rotational speed to the time the rotation was stopped was 5 seconds. Such a rotation process was designated as one cycle, and this cycle was repeated. The period of time for crystal growth was 12 hours.

### [Inspection Procedure]

For the SiC single crystals of Examples and the SiC single crystal of Comparative Example, the cross-section of each of them was examined and inspected for the presence or absence of inclusions.

### [Inspection Result]

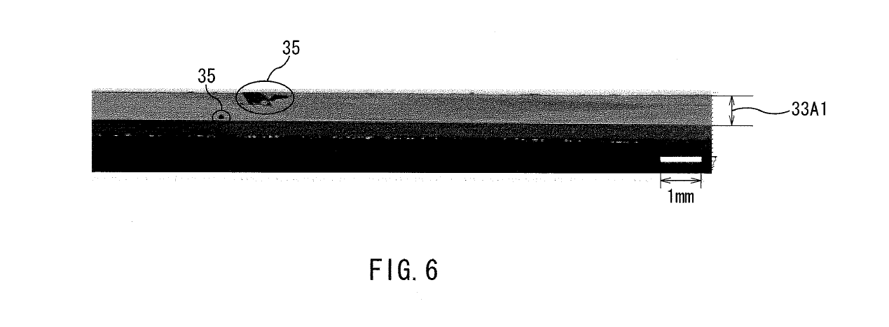

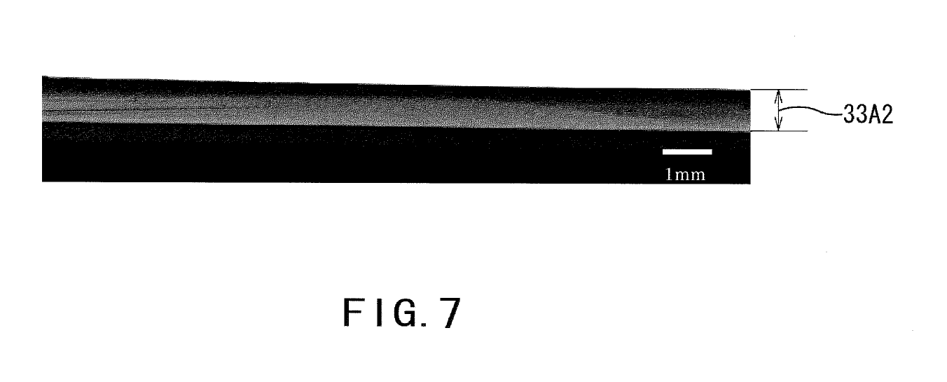

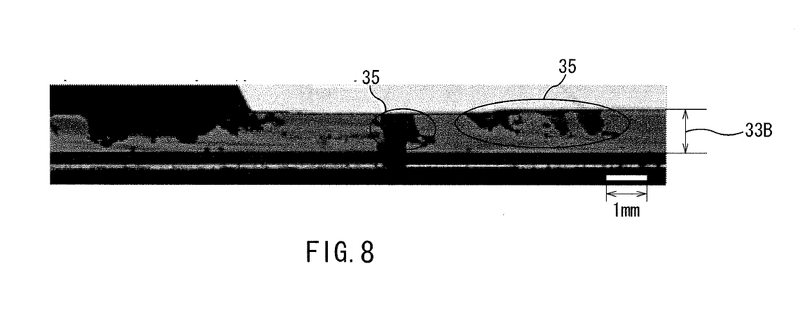

FIG. 6 is a photograph of a section of a SiC single crystal 33A1 of Example 1. FIG. 7 is a photograph of a section of a SiC single crystal 33A2 of Example 2. FIG. 8 is a photograph of a section of a SiC single crystal 33B of Comparative Example.

It is seen from FIGS. 6 to 8 that the occurrence of inclusions 35 was inhibited in the SiC single crystals 33A1 and 33A2 of Examples 1 and 2, compared to the SiC single crystal 33B of Comparative Example. As for the SiC single crystal 33A2 of Example 2, no inclusions are seen in the section of FIG. 7. Also, it is seen that the surfaces of the SiC single crystals 33A1 and 33A2 of Examples 1 and 2 (particularly Example 2) are relatively flat compared to the surface of the SiC single crystal 33B of Comparative Example.

This is believed to be because, in the SiC single crystals 33A1 and 33A2 of Examples 1 and 2, compared to the SiC single crystal 33B of Comparative Example, clusters of the solute in the Si—C solution were sufficiently dissociated during the production of the crystals and therefore step bunching was inhibited.

Although specific embodiments of the present invention have been described in the foregoing, these are merely for illustrative purposes and are not intended in any way to limit the scope of the invention.

### REFERENCE SIGNS LIST

10: production apparatus, 14: crucible, 15: Si—C solution, 26: drive source, 28: seed shaft, 28S: lower end surface, 32: SiC seed crystal, 34: cylindrical portion, 36: bottom portion, 38: flow control portion, 381: opening, 382: inner surface (flow control surface)

1.-9. (canceled)

10. A production apparatus for use in producing a single crystal by a solution growth technique, the apparatus comprising:
a seed shaft having a lower end surface to which a seed crystal is to be attached;
a crucible configured to contain a solution from which the single crystal is made; and
a drive source configured to cause the crucible to rotate and to vary a rotational speed of the crucible;
wherein the crucible has an inner peripheral surface, the inner peripheral surface including a flow control surface, the flow control surface defining a non-circular cross-sectional shape.

11. The production apparatus according to claim 10,
wherein the cross-sectional shape defined by the flow control surface has point symmetry.

12. The production apparatus according to claim 11,
wherein the cross-sectional shape defined by the flow control surface is oval.

13. The production apparatus according to claim 10,
wherein the crucible includes:
a cylindrical portion;
a bottom portion located at a lower end of the cylindrical portion; and
a flow control portion disposed in contact with the cylindrical portion and having an opening extending vertically, the opening having an inner surface, the inner surface constituting the flow control surface.

14. The production apparatus according to claim 11,
wherein the crucible includes:
a cylindrical portion;
a bottom portion located at a lower end of the cylindrical portion; and
a flow control portion disposed in contact with the cylindrical portion and having an opening extending vertically, the opening having an inner surface, the inner surface constituting the flow control surface.

15. The production apparatus according to claim 12,
wherein the crucible includes:
a cylindrical portion;
a bottom portion located at a lower end of the cylindrical portion; and
a flow control portion disposed in contact with the cylindrical portion and having an opening extending vertically, the opening having an inner surface, the inner surface constituting the flow control surface.

16. The production apparatus according to claim 13,
wherein the flow control portion is positioned in contact with the bottom portion.

17. The production apparatus according to claim 14,
wherein the flow control portion is positioned in contact with the bottom portion.

18. The production apparatus according to claim 15,
wherein the flow control portion is positioned in contact with the bottom portion.

19. The production apparatus according to claim 13,
wherein the flow control portion has an outer peripheral surface that includes:
a first outer peripheral surface that is brought into contact with the cylindrical portion; and
a second outer peripheral surface that is spaced apart from the cylindrical portion.

20. The production apparatus according to claim 14,
wherein the flow control portion has an outer peripheral surface that includes:
a first outer peripheral surface that is brought into contact with the cylindrical portion; and
a second outer peripheral surface that is spaced apart from the cylindrical portion.

21. The production apparatus according to claim 15,
wherein the flow control portion has an outer peripheral surface that includes:
a first outer peripheral surface that is brought into contact with the cylindrical portion; and
a second outer peripheral surface that is spaced apart from the cylindrical portion.

22. The production apparatus according to claim 16,
wherein the flow control portion has an outer peripheral surface that includes:
a first outer peripheral surface that is brought into contact with the cylindrical portion; and
a second outer peripheral surface that is spaced apart from the cylindrical portion.

23. The production apparatus according to claim 17,
wherein the flow control portion has an outer peripheral surface that includes:
a first outer peripheral surface that is brought into contact with the cylindrical portion; and
a second outer peripheral surface that is spaced apart from the cylindrical portion.

24. The production apparatus according to claim 18,
wherein the flow control portion has an outer peripheral surface that includes:
a first outer peripheral surface that is brought into contact with the cylindrical portion; and
a second outer peripheral surface that is spaced apart from the cylindrical portion.

25. The production apparatus according to claim 10,
wherein the seed crystal is a SiC seed crystal and the solution is a Si—C solution.

26. A crucible for use in a production apparatus for producing a single crystal by a solution growth technique and configured to contain a material for the single crystal,
the crucible comprising an inner peripheral surface, the inner peripheral surface including a flow control surface, the flow control surface defining a non-circular cross-sectional shape.

27. A method of producing a single crystal by a solution growth technique, the method comprising the steps of:
preparing a seed shaft having a lower end surface to which a seed crystal is to be attached;
preparing a crucible configured to contain a solution from which the single crystal is made, the crucible having an inner peripheral surface, the inner peripheral surface including a flow control surface, the flow control surface defining a non-circular cross-sectional shape;
forming the solution; and
bringing the seed crystal into contact with the solution and growing the single crystal,
wherein the step of growing the single crystal includes causing the crucible to rotate and varying a rotational speed of the crucible.
